(19) United States
(12) Patent Application Publication
(10) Pub. No.: US 2019/0118309 A1
(43) Pub. Date: Apr. 25, 2019

(54) JOINT STRUCTURE, ELECTRONIC COMPONENT MODULE, ELECTRONIC COMPONENT UNIT, AND METHOD OF MANUFACTURING ELECTRONIC COMPONENT UNIT

(71) Applicant: TDK CORPORATION, Tokyo (JP)

(72) Inventors: Yohei HIROTA, Tokyo (JP); Hiroshi YAMAZAKI, Tokyo (JP)

(73) Assignee: TDK CORPORATION, Tokyo (JP)

(21) Appl. No.: 16/158,710

(22) Filed: Oct. 12, 2018

(30) Foreign Application Priority Data
Oct. 25, 2017 (JP) 2017-206175

(51) Int. Cl. B23K 35/26; B32B 15/01; C22C 13/00; C22C 1/04; C22C 19/03; H05K 1/11; H05K 1/18; H01L 23/00

(52) U.S. Cl. CPC B23K 35/262; B32B 15/01; C22C 13/00; C22C 1/0433; C22C 1/0483; C22C 19/03; H01L 2224/05572; H05K 1/181; H01L 24/48; H01L 24/05; H01L 2924/013; H01L 2224/05655; H05K 1/11

(57) ABSTRACT

A joint structure includes a first metal part and a second metal part. The first metal part includes a nickel-iron alloy or copper. The second metal part is provided adjacent to the first metal part and includes tin. Out of the first metal part and the second metal part, the first metal part includes a plurality of first metal parts, or out of the first metal part and the second metal part, the second metal part includes a plurality of second metal parts, or the first metal part includes the plurality of first metal parts and the second metal part includes the plurality of second metal parts.

### CROSS REFERENCE TO RELATED APPLICATIONS

This application claims the benefit of Japanese Priority Patent Application No. 2017-206175 filed on Oct. 25, 2017, the entire contents of which are incorporated herein by reference.

### BACKGROUND

The disclosure relates to a joint structure that joins two or more objects to each other, an electronic component module including the joint structure, an electronic component unit including the joint structure, and a method of manufacturing the electronic component unit.

Some electronic component modules have been proposed each of which includes a plurality of electronic components that are modularized. For example, Japanese Unexamined Patent Application Publication No. 2009-76588 discloses a sensor package that accommodates a sensor chip including an acceleration sensor and fixed to an application-specific integrated circuit (ASIC) through an adhesive resin layer. Japanese Unexamined Patent Application Publication No. 2016-87691 discloses a module that accommodates an electronic component soldered to a substrate by means of a lead (Pb)-free paste. Japanese Unexamined Patent Application Publication No. H09-181125 discloses a mutual joint structure that is suitable for coupling a microelectronic circuit chip to a package. The mutual joint structure includes a solderable layer including a metal, such as a nickel-iron (NiFe) alloy, and a tin-based and lead-free solder ball provided on the solderable layer. Japanese Unexamined Patent Application Publication No. H08-316629 discloses a module substrate that includes two opposite substrates joined to each other through a pillar member. The pillar member includes a copper columnar body surrounded with a solder material.

### SUMMARY

A joint structure according to one embodiment of the disclosure includes a first metal part including a nickel-iron alloy or copper, and a second metal part provided adjacent to the first metal part and including tin. Out of the first metal part and the second metal part, the first metal part includes a plurality of first metal parts, or out of the first metal part and the second metal part, the second metal part includes a plurality of second metal parts, or the first metal part includes a plurality of first metal parts and the second metal part includes a plurality of second metal parts.

An electronic component module according to one embodiment of the disclosure includes an electronic component chip including an electronic component, and a joint structure provided on the electronic component chip. The joint structure includes a first metal part and a second metal part. The first metal part includes a nickel-iron alloy or copper. The second metal part is provided adjacent to the first metal part and includes tin. Out of the first metal part and the second metal part, the first metal part includes a plurality of first metal parts, or out of the first metal part and the second metal part, the second metal part includes a plurality of second metal parts, or the first metal part includes a plurality of first metal parts and the second metal part includes a plurality of second metal parts.

An electronic component unit according to one embodiment of the disclosure includes a first substrate including a first electronic component, a second substrate including a second electronic component, and a joint structure joining the first substrate and the second substrate. The joint structure includes a first metal part and a second metal part. The first metal part includes a nickel-iron alloy or copper. The second metal part is provided adjacent to the first metal part and includes tin. Out of the first metal part and the second metal part, the first metal part includes a plurality of first metal parts, or out of the first metal part and the second metal part, the second metal part includes a plurality of second metal parts, or the first metal part includes the plurality of first metal parts and the second metal part includes the plurality of second metal parts.

A method of manufacturing an electronic component unit according to one embodiment of the disclosure includes: forming a joint structure on a first substrate that includes a first electronic component, the joint structure including a first metal part that includes a nickel-iron alloy or copper and a second metal part that is provided adjacent to the first metal part and includes tin, out of the first metal part and the second metal part, the first metal part including a plurality of first metal parts, or out of the first metal part and the second metal part, the second metal part including a plurality of second metal parts, or the first metal part including the plurality of first metal parts and the second metal part including the plurality of second metal parts; providing a second substrate on a first surface of the joint structure, the second substrate including a second electronic component, the first surface of the joint structure being opposite to a second surface of the joint structure, the second surface of the joint structure facing the first substrate; and forming an alloy of the nickel-iron alloy or the copper included in the first metal part and the tin included in the second metal part by heating the first metal part and the second metal part.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the disclosure.

FIG. 1A is a schematic plan view of a joint structure having an example configuration according to one embodiment of the disclosure.

FIG. 1B is a schematic perspective view of the joint structure illustrated in FIG. 1A.

FIG. 1C is a schematic characteristic diagram illustrating an example distribution of a tin content rate of the joint structure illustrated in FIG. 1A.

FIG. 2 is a schematic cross-sectional view of an example electronic component unit according to one embodiment of the disclosure to which the joint structure illustrated in FIG. 1A is applied.

FIG. 3A is a schematic cross-sectional view of the electronic component unit illustrated in FIG. 2 for illustrating an example process in a method of manufacturing the electronic component unit according to one embodiment of the disclosure.

FIG. 3B is a schematic cross-sectional view of the electronic component unit for illustrating an example process following the process illustrated in FIG. 3A.

FIG. 3C is a schematic cross-sectional view of the electronic component unit for illustrating an example process following the process illustrated in FIG. 3B.

FIG. 3D is a schematic cross-sectional view of the electronic component unit for illustrating an example process following the process illustrated in FIG. 3C.

FIG. 4A is a schematic plan view of a joint structure according to one embodiment of the disclosure for illustrating a state of the joint structure before a heating process.

FIG. 4B is a schematic perspective view of the joint structure illustrated in FIG. 4A for illustrating a state of the joint structure before the heating process.

FIG. 5 is a schematic perspective view of a joint structure having an example configuration according to one embodiment of the disclosure.

FIG. 6A is a schematic cross-sectional view of an example electronic component unit according to one modification of the disclosure for illustrating an example process in a method of manufacturing the electronic component unit.

FIG. 6B is a schematic cross-sectional view of the electronic component unit for illustrating an example process following the process illustrated in FIG. 6A.

FIG. 6C is a schematic cross-sectional view of the electronic component unit for illustrating an example process following the process illustrated in FIG. 6B.

FIG. 6D is a schematic cross-sectional view of the electronic component unit for illustrating an example process following the process illustrated in FIG. 6C.

FIG. 7 is a schematic cross-sectional view of an example electronic component unit according to one embodiment of the disclosure to which the joint structure illustrated in FIG. 1A is applied.

FIG. 8 is a schematic plan view of a joint structure having an example configuration according to one modification of the disclosure.

FIG. 9 is a schematic plan view of a joint structure having an example configuration according to one modification of the disclosure.

### DETAILED DESCRIPTION

A region in which a joint structure is formed has been increasingly narrowed for a higher packaging density of electronic components in an electronic component module. A higher packaging density of electronic components, however, may possibly cause short-circuiting in circuitry including the electronic components due to the joint structure melted by reheating.

It is desirable to provide a joint structure having superior quality, an electronic component module including the joint structure, an electronic component unit including the joint structure, and a method of manufacturing the electronic component unit.

In the following, some example embodiments of the disclosure are described in detail, in the following order, with reference to the accompanying drawings. Note that the following description is directed to illustrative examples of the disclosure and not to be construed as limiting the disclosure. Factors including, without limitation, numerical values, shapes, materials, components, positions of the components, and how the components are coupled to each other are illustrative only and not to be construed as limiting the disclosure. Further, elements in the following example embodiments which are not recited in a most-generic independent claim of the disclosure are optional and may be provided on an as-needed basis. The drawings are schematic and are not intended to be drawn to scale. Note that the like elements are denoted with the same reference numerals, and any redundant description thereof will not be described in detail. Note that the description is given in the following order.

### 1. First Embodiment (Example Joint Structure Including First Metal Part Surrounding Second Metal Parts)

### 1.1 Example Configuration of Joint Structure

### 1.2 Example Electronic Component Module Including Joint Structure and Example Electronic Component Unit Including Joint Structure

### 1.3 Example Method of Manufacturing Electronic Component Unit Including Joint Structure

### 1.4 Workings and Effects of Electronic Component Unit Including Joint Structure

### 2. Second Embodiment (Example Joint Structure Including Alternate Laminate of First Metal Layers and Second Metal Layers)

### 3. Modifications

### 1. First Embodiment

### 1.1 Example Configuration of Joint Structure 1

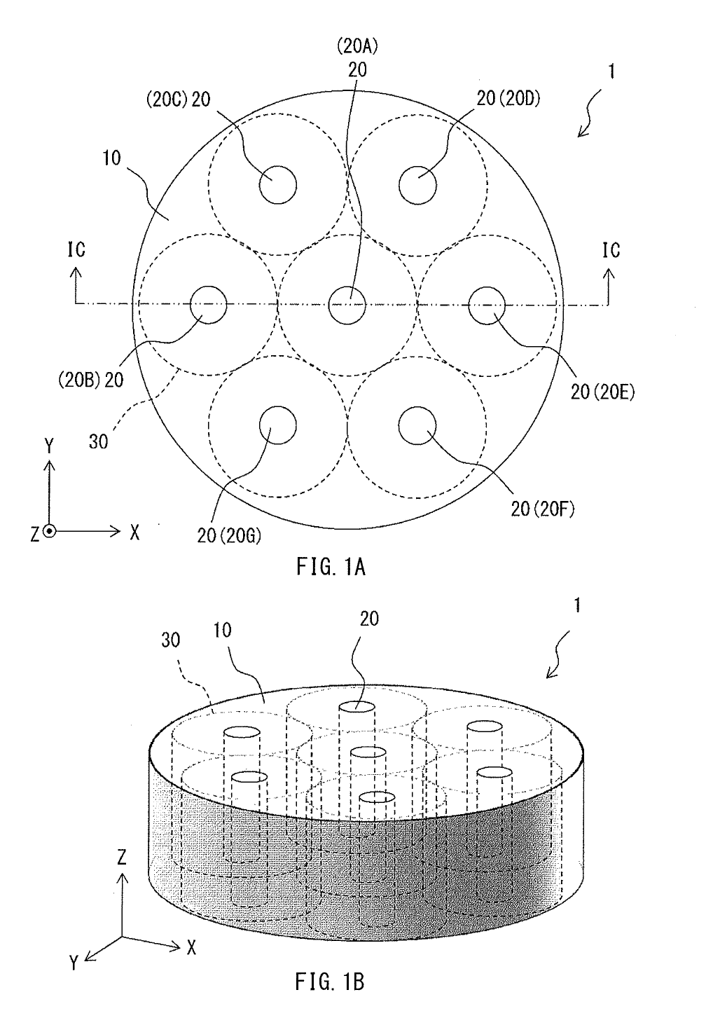

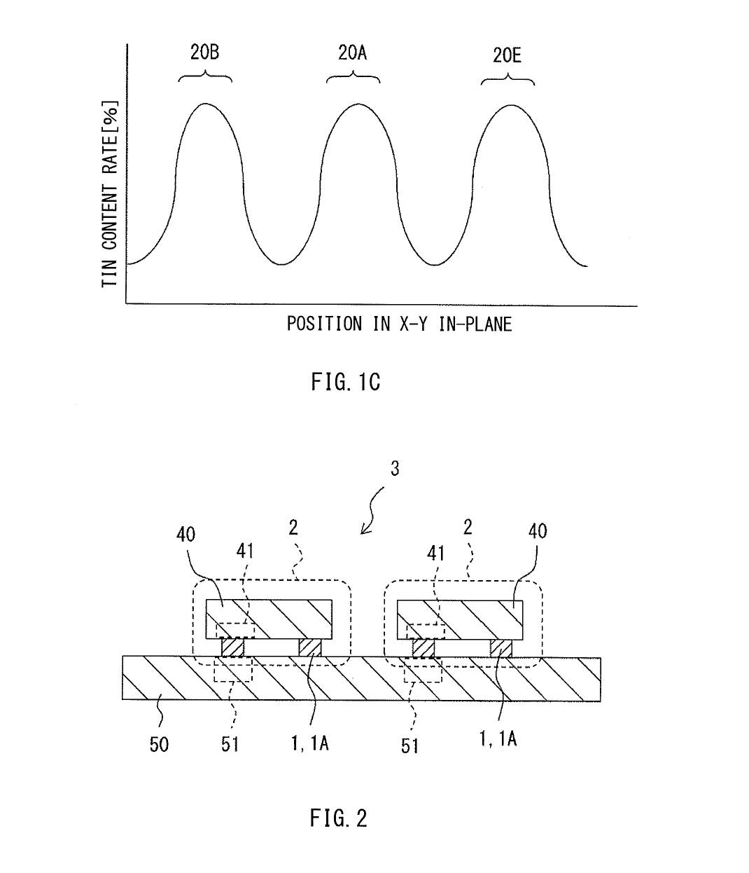

FIG. 1A is a schematic top view of a joint structure 1 having an example configuration according to a first embodiment of the disclosure, and FIG. 1B is a schematic perspective view of the joint structure 1 illustrated in FIG. 1A.

The joint structure 1 includes a first metal part 10 and a plurality of second metal parts 20. The first metal part 10 includes a nickel-iron (NiFe) alloy or copper (Cu). The second metal parts 20 are provided adjacent to the first metal part 10 and include tin (Sn). In the first embodiment, the first metal part 10 may have a substantially columnar shape, and the second metal parts 20 may each have a substantially cylindrical pillar shape. The second metal parts 20 may be provided discretely in an X-Y in-plane. The pillar-shaped second metal parts 20 hereinafter may also be referred to as “second metal pillars 20 (20A to 20G)”.

In the first embodiment, the first metal part 10 may be filled in gaps between the second metal parts 20 extending in a thickness direction of the joint structure 1 along a Z-axis. As illustrated by a dashed-line in FIGS. 1A and 1B, an alloy region 30 may be provided at an interface between the first metal part 10 and each of the second metal parts 20. The alloy regions 30 may include an alloy of a constituent element (i.e., nickel, iron, or copper) of the first metal part 10 and a constituent element (i.e., tin) of the second metal parts 20. With reference to FIGS. 1A and 1B, a region defined between the dashed-line circle (cylinder) and a solid-line indicating each second metal part 20 may correspond to the alloy region 30. Optionally, the first metal part 10 may further include a tin-nickel-iron alloy or a tin-copper alloy, and the second metal parts 20 may further include a tin-nickel-iron alloy or a tin-copper alloy. It should be noted that, even in such a case, each of the second metal parts 20 may have a tin content rate that is greater than the tin content rate of the first metal part 10. The tin content rate of the first metal part 10 may correspond to a specific but non-limiting example of a “first tin content rate” according to one embodiment of the disclosure, and the tin content rate of each of the second metal parts 20 may correspond to a specific but non-limiting example of a “second tin content rate” according to one embodiment of the disclosure. It should also be noted that, although the alloy regions 30 are schematically illustrated by the respective dash-line circles in FIGS. 1A and 1B, the alloy regions 30 may be enlarged and integrated with each other so as not to form a gap therebetween, in an alternative example embodiment of the disclosure. In an example embodiment of the disclosure, no tin in the form of a metal simple substance may be included in the second metal parts 20 and all the tin included in the joint structure 1 is alloyed with the NiFe or copper.

In the joint structure 1, one of the second metal parts 20 (e.g., the second metal pillar 20A) may be surrounded by the other second metal parts 20 (e.g., the second metal pillars 20B to 20G). For example, the second metal pillars 20B to 20G may be respectively provided at the six vertices of a regular hexagon centering around the second metal pillar 20A. In other words, the centers of the the second metal pillars 20A to 20G may be positioned at an equal interval.

FIG. 1C is a schematic characteristic diagram illustrating an example distribution of the tin content rate along an X-Y in-plane direction orthogonal to the thickness direction along the Z-axis. The diagram illustrated in FIG. 1C has a horizontal axis indicating a position along the section line IC-IC in FIG. 1A, and a vertical axis indicating a percentage (%) of the tin content rate. As illustrated in FIG. 1C, the joint structure 1 may have a part in which the tin content rate repeatedly varies along the X-Y in-plane direction. Peaks of the curve of FIG. 1C may correspond to the second metal pillars 20B, 20A, and 20E, respectively.

### 1.2 Example Electronic Component Module Including Joint Structure 1 and Example Electronic Component Unit thereof

FIG. 2 is a schematic cross-sectional view of an electronic component module 2 including the joint structure 1 illustrated in FIGS. 1A and 1B and an electronic component unit 3 including the electronic component module 2.

Referring to FIG. 2, the electronic component unit 3 may include one or more electronic component modules 2 provided on an application-specific integrated circuit (ASIC) 50, for example. In an example embodiment of the disclosure illustrated in FIG. 2, the electronic component unit 3 may include two electronic component modules 2 provided on a single ASIC 50. The ASIC 50 may include, for example, semiconductor devices 51. The electronic component modules 2 may each include a sensor chip 40 and the joint structure 1 provided at the sensor chip 40. The sensor chip 40 may include a sensor 41 that includes, for example, a tunnel magneto-resistive (TMR) element. In the electronic component unit 3 illustrated in FIG. 2, the sensor chip 40 may be mechanically fixed to the ASIC 50 through the joint structure 1. Additionally, the semiconductor device 51 and the corresponding sensor 41 may be electrically coupled to each other through the joint structure 1 having electrical conductivity. Note that the semiconductor device 51 may correspond to a specific but non-limiting example of a “first electronic component” according to one embodiment of the disclosure, and the ASIC 50 may correspond to a specific but non-limiting example of a “first substrate” according to one embodiment of the disclosure. The sensor 41 may correspond to a specific but non-limiting example of a “second electronic component” and an “ electronic component” according to one embodiment of the disclosure, and the sensor chip 40 may correspond to a specific but non-limiting example of a “second substrate” and an “electronic component chip” according to one embodiment of the disclosure.

### 1.3 Example Method of Manufacturing Electronic Component Unit 3 Including Joint Structure 1

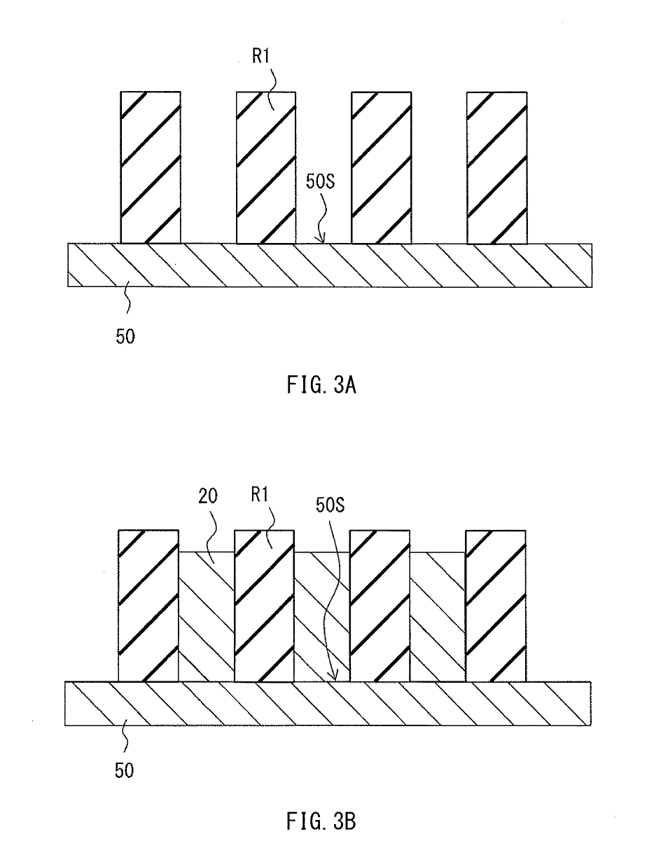

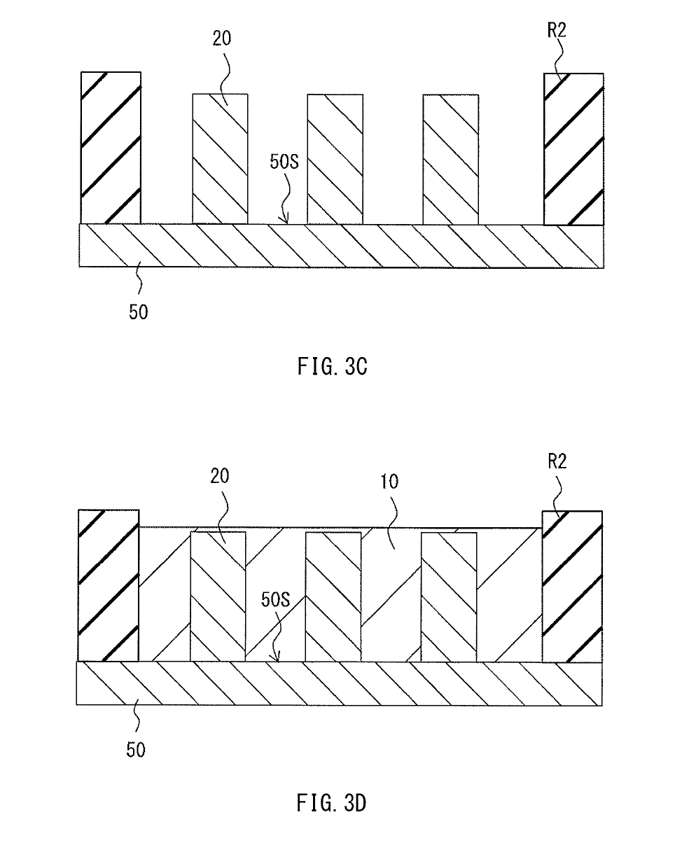

An example method of manufacturing the electronic component unit 3 including the joint structure 1 according to an example embodiment of the disclosure will now be described with reference to FIGS. 3A to 3D. Each of FIGS. 3A to 3D is a schematic cross-sectional diagram illustrating an example process in the method of manufacturing the electronic component unit 3 illustrated in FIG. 2.

First, the joint structure 1 is formed on a surface 50S of the ASIC 50 including the semiconductor devices 51, as follows. With reference to FIG. 3A, for example, a resist pattern R1 may be formed to cover a selective region of the surface 50S of the ASIC 50. The selective region may correspond to a region in which the first metal part 10 is to be formed.

Thereafter, with reference to FIG. 3B, regions not covered with the resist pattern R1 may be filled with a tin (Sn)-based metal by plating, for example, to form the plurality of pillar-shaped second metal parts 20 (i.e., the second metal pillars 20).

Thereafter, the resist pattern R1 may be removed, and a resist pattern R2 may be formed in a selective region so as to surround the second metal pillars 20, as illustrated in FIG. 3C. The resist pattern R2 may define an outer periphery of the first metal part 10 to be formed.

Thereafter, with reference to FIG. 3D, a region not covered with the resist pattern R2 may be filled with a metal including NiFe or copper by plating, for example, to form the first metal part 10 filled in the gaps between the second metal parts 20.

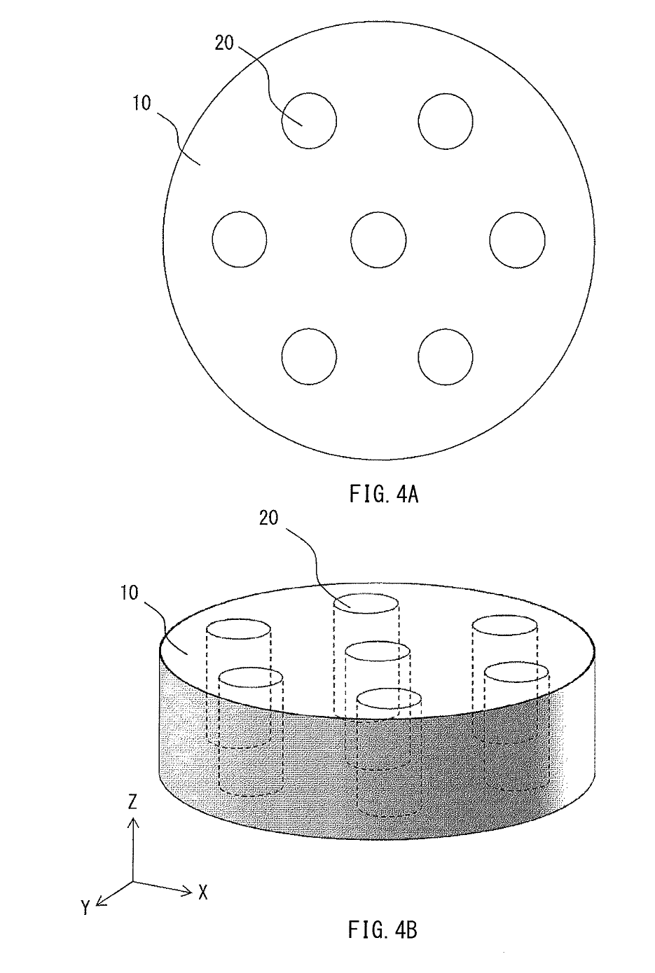

Finally, the resist pattern R2 may be removed to produce the joint structure 1 on the surface 50S of the ASIC 50, as illustrated in FIGS. 4A and 4B. Note that FIG. 4A is a top view of the joint structure 1 before a heating process described below and FIG. 4B is a perspective view of the joint structure 1 illustrated in FIG. 4A.

Although the foregoing description with reference to FIGS. 3A to 3D focuses on the method of manufacturing a single joint structure 1, a plurality of joint structures 1 having the same or similar structure may be manufactured together through the method according to any embodiment of the disclosure.

After the formation of the joint structure 1, the sensor chip 40 including the sensor 41 is provided on a first surface of the joint structure. The first surface of the joint structure 1 is opposite to a second surface, facing the ASIC 50, of the joint structure 1. In other words, the sensor chip 40 is disposed on the joint structure 1 that is provided on the surface 50S of the ASIC 50. The joint structure 1 in such a state may be heated and melted followed by being cooled, so that the sensor chip 40 may be joined to the ASIC 50 through the joint structure 1. During the heating process performed on the joint structure 1, the tin included in the second metal parts 20 is diffused to the first metal part 10 surrounding the second metal parts 20, forming the alloy regions 30, as illustrated in FIGS. 1A and 1B. After the heating process, the second metal parts 20 may decrease in their volume, compared with the second metal parts 20 before the heating process that are illustrated in FIGS. 4A and 4B.

The electronic component unit 3 may be manufactured through the processes described above.

### 1.4 Workings and Effects of Electronic Component Unit Including Joint Structure

According to any example embodiment of the disclosure, the joint structure 1 includes the first metal part 10 and the plurality of second metal parts 20. The first metal part 10 includes a nickel-iron alloy or copper. The second metal parts 20 are provided adjacent to the first metal part 10 and include tin (Sn). Thus, after the heating process performed on such a joint structure 1, the two or more alloy regions 30 may be formed that include an alloy of the constituent element of the first metal part 10 and the constituent element of the second metal parts 20. This raises the melting point of the joint structure 1, improves structural uniformity across the entire joint structure 1, and reduces variations in quality of the joint structure 1. Therefore, according to any example embodiment of the disclosure, it is possible to ensure superior quality of the joint structure 1 that has, for example, a high melting point owing to the formation of the alloy regions 30, and high resistance to deformation and remelting even after reheating in a subsequent process. Further, according to the method of manufacturing of the electronic component unit 3 of any example embodiment of the disclosure, it is possible to produce the electronic component unit 3 having the superior quality.

According to an example embodiment of the disclosure, the first metal part 10 may further include a tin-nickel-iron alloy or a tin-copper alloy, and the second metal part 20 may further include a tin-nickel-iron alloy or a tin-copper alloy. This mitigates variations in quality across the entire joint structure 1. Accordingly, it is possible to join the ASIC 50 and the sensor chip 40 more firmly by melting the joint structure 1 in an initial heating. It is also possible to maintain the joint between the ASIC 50 and the sensor chip 40 more securely, since the joint structure 1 is resistant to remelting during the reheating.

According to an example embodiment of the disclosure, the tin-based second metal parts 20 may be the plurality of pillars extending along the Z-axis, and the first metal part 10 including the nickel-iron alloy or copper may be filled in the gaps between the second metal parts 20. The joint structure 1 having a such configuration has reduced variations in metal composition along the Z-axis, compared with, for example, a joint structure 1A according to a second embodiment described below in which first metal parts 11 and second metal parts 21 are alternately laminated along the Z-axis. Accordingly, it is possible to enhance the joint strength between the ASIC 50 and the sensor chip 40 that are joined along the Z-axis through the joint structure 1. Further, according to such an example embodiment of the disclosure, the melting point of the nickel-iron alloy or copper included in the columnar first metal part 10 is higher than the melting point of the tin included in the second metal parts 20 surrounded by the first metal part 10. Accordingly, it is possible to maintain a distance between the sensor chip 40 and the ASIC 50 more accurately than another example embodiment of the disclosure in which a plurality of first metal parts 10 including the nickel-iron alloy or copper and each having a pillar shape are provided and the tin-based second metal part 20 is filled in gaps between the first metal parts 10. Furthermore, since tin has a lower melting point than a nickel-iron alloy or copper and thus has high wettability, the tin-based second metal parts 20 are in well contact with the surface of the ASIC 50 and the surface of the sensor chip 40. Therefore, according to such an example embodiment of the disclosure, it is possible to enhance the joint strength between the ASIC 50 and the sensor chip 40.

According to an example embodiment of the disclosure, one of the second metal parts 20 (e.g., the second metal pillar 20A) may be surrounded by the other second metal parts 20 (e.g., the second metal pillars 20B to 20G). This achieves a homogeneous distribution of the second metal parts 20 and the alloy regions 30 surrounding the respective second metal parts 20 in the X-Y in-plane. Accordingly, it is possible to join the ASIC 50 and the sensor chip 40 even more firmly and maintain the joint even more securely.

According to an example embodiment of the disclosure, the joint structure 1 may have a part in which the tin content rate repeatedly varies along the X-Y in-plane direction. Accordingly, it is possible to firmly join the ASIC 50 and the sensor chip 40, for example, by melting, in the initial heating, the tin, which has a relatively low melting point, in the plurality of parts having a high tin content rate. Further, since the tin may be alloyed with the nickel-iron alloy (or copper) in the initial heating, it is possible to achieve the joint structure 1 resistant to remelting during the reheating, after the joint structure 1 is once cooled after the initial heating.

According to an example embodiment of the disclosure, the sensor chip 40 and the ASIC 50 may be electrically coupled through the joint structure 1. This eliminates a need for wire bonding that electrically couples the sensor chip 40 and the ASIC 50. Accordingly, it is possible to suppress or prevent troubles, such as short-circuiting between adjacent wiring lines and breaking due to disconnection between wiring lines. In turn, it is possible to enhance reliability of the electronic component module 2 or the electronic component unit 3.

### Second Embodiment

### Example Configuration of Joint Structure 1A

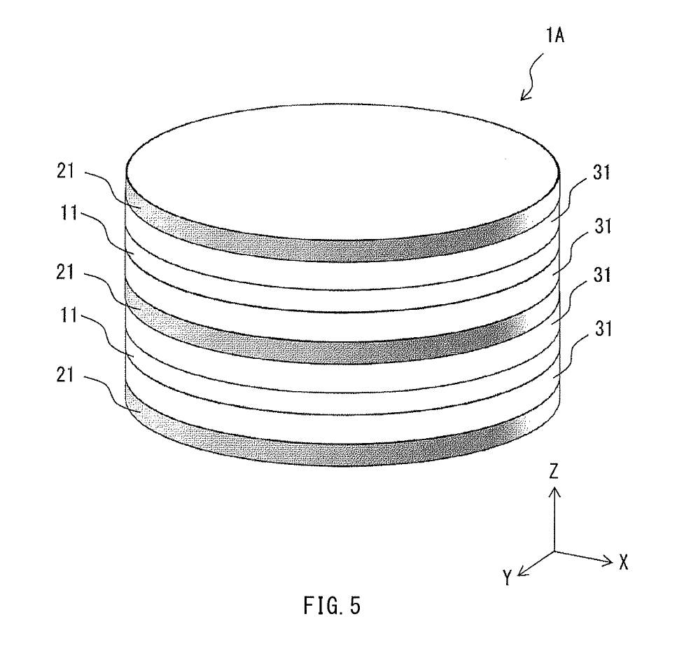

FIG. 5 is a schematic perspective view of a joint structure 1A having an example configuration according to a second embodiment of the disclosure. The joint structure 1A includes a plurality of first metal layers 11 and a plurality of second metal layers 21 that are alternately laminated along the Z-axis. The first metal layer 11 may correspond to a specific but non-limiting example of the “first metal part” according to one embodiment of the disclosure, and the second metal layer 21 may correspond to a specific but non-limiting example of the “second metal part” according to one embodiment of the disclosure.

The first metal layers 11 each include a nickel-iron alloy or copper, similarly to the first metal part 10 of the first embodiment of the disclosure. The second metal layers 21 are provided adjacent to the respective first metal layers 11 and include tin, similarly to the second metal parts 20 of the first embodiment of the disclosure. According to an example embodiment of the disclosure, the uppermost layer and the undermost layer of the joint structure 1A may be the tin-based second metal layers 21. To join target objects, such as the ASIC 50 and the sensor chip 40, to each other, the uppermost layer and the undermost layer are portions to be in contact with the respective target objects. Accordingly, the joint structure 1A having the uppermost layer and the undermost layer that are the second metal layers 21 having a lower melting point than the first metal layers 11 facilitates joining by heat-welding.

The joint structure 1A may further include an alloy region 31 at an interface between each of the first metal layers 11 and adjacent one of the second metal layers 21. The alloy regions 31 may include an alloy of the nickel-iron alloy included in the first metal layer 11 and the tin included in the second metal layer 21, or an alloy of the copper included in the first metal layer 11 and the tin included in the second metal layer 21. Optionally, the first metal layers 11 may further include a tin-nickel-iron alloy or a tin-copper alloy, and the second metal layers 21 may further include a tin-nickel-iron alloy or a tin-copper alloy. It should be noted that, even in such a case, each of the second metal layers 21 may have a tin content rate that is greater than the tin content rate of each of the first metal layers 11. The tin content rate of each of the first metal layers 11 may correspond to a specific but non-limiting example of a “first tin content rate” according to one embodiment of the disclosure. The tin content rate of each of the second metal layers 21 may correspond to a specific but non-limiting example of a “second tin content rate” according to one embodiment of the disclosure.

Similarly to the joint structure 1 illustrated in FIGS. 1A and 1B, the joint structure 1A may be applicable to the electronic component module 2 and the electronic component unit 3 including the electronic component module 2 that are illustrated in FIG. 2.

The joint structure 1A may be manufactured by alternately laminating the second metal layers 21 and the first metal layers 11 on a substrate, such as the sensor chip 40 or the ASIC 50. The electronic component unit 3 including the joint structure 1A is manufactured by forming the joint structure 1A on the ASIC 50, for example, providing the sensor chip 40 so as to face the ASIC 50 across the joint structure 1A, and performing a heating process. During the heating process performed on the joint structure 1A, the tin included in the second metal layers 21 is diffused to the first metal layers 11 surrounding the second metal layers 21, forming the alloy regions 31.

### Workings and Effects of Joint Structure 1A

According to an example embodiment of the disclosure described above, the joint structure 1A includes the first metal layers 11 and the second metal layers 21. The first metal layers 11 each include a nickel-iron alloy or copper. The second metal layers 21 are provided adjacent to corresponding one of the first metal layers 11 and include tin (Sn). Thus, after the heating process performed on such a joint structure 1A, the two or more alloy regions 31 may be formed that include an alloy of the constituent element of the first metal layers 11 and the constituent element of the second metal layer 21. This raises the melting point of the joint structure 1A, improves structural uniformity across the entire joint structure 1A, and reduces variations in quality of the joint structure 1A. Therefore, according to such an example embodiment of the disclosure, it is possible to ensure superior quality of the joint structure 1A that has, for example, a high melting point owing to the formation of the alloy regions 31, and high resistance to deformation and remelting even after reheating in a subsequent process. Further, according to the method of manufacturing of the electronic component unit 3 of any example embodiment of the disclosure, it is possible to produce the electronic component unit 3 having the superior quality.

According to an example embodiment of the disclosure, the first metal layers 11 may further include a tin-nickel-iron alloy or a tin-copper alloy, and the second metal layers 21 may further include a tin-nickel-iron alloy or a tin-copper alloy. This mitigates variations in quality across the entire joint structure 1A. Accordingly, it is possible to join the ASIC 50 and the sensor chip 40 more firmly by melting the joint structure 1A in the initial heating. It is also possible to maintain the joint between the ASIC 50 and the sensor chip 40 more securely, since the joint structure 1A is resistant to remelting during the reheating.

According to an example embodiment of the disclosure, the sensor chip 40 and the ASIC 50 may be electrically coupled through the joint structure 1A. This eliminates a need for wire bonding that electrically couples the sensor chip 40 and the ASIC 50. Accordingly, it is possible to suppress or prevent troubles, such as short-circuiting between adjacent wiring lines and breaking due to disconnection between wiring lines. In turn, it is possible to enhance reliability of the electronic component module 2 or the electronic component unit 3.

Additionally, the joint structure 1A has a simpler structure than the joint structure 1 according to the first embodiment of the disclosure described above, and thus is more readily manufactured than the joint structure 1.

### 3. Modifications

Although the disclosure has been described with reference to the foregoing example embodiments, the disclosure is not limited thereto, but may be modified in a wide variety of ways.

For example, factors such as a shape, arrangement, and number of the components of the joint structures 1 and 1A exemplified in any example embodiment and modifications are illustrative and non-limiting. Any other shape, arrangement, and number of the components may be adopted besides those described above.

In the first embodiment of the disclosure, the tin-based second metal parts may be the plurality of pillars, and the first metal part 10 including the nickel-iron alloy or copper may be filled in the gaps between the second metal parts 20. It should be appreciated that the configuration of the joint structure 1 according to the first embodiment is not to be construed as limiting the disclosure. In an example modification of the disclosure, a plurality of first metal parts 10 each including the nickel-iron alloy or copper and each having a pillar shape may be provided and the tin-based second metal part 20 may be filled in gaps between the first metal parts 10. The melting point of the nickel-iron alloy (about 1450° C.) and the melting point of the copper (about 1083° C.) are higher than that of the tin (about 232° C.). Therefore, in this example modification, the tin filled in the gaps between the plurality of first metal parts 10 is melted by the heating process to join substrates of two electronic components. Accordingly, the example modification is advantageous in firmly joining the substrates of two electronic components.

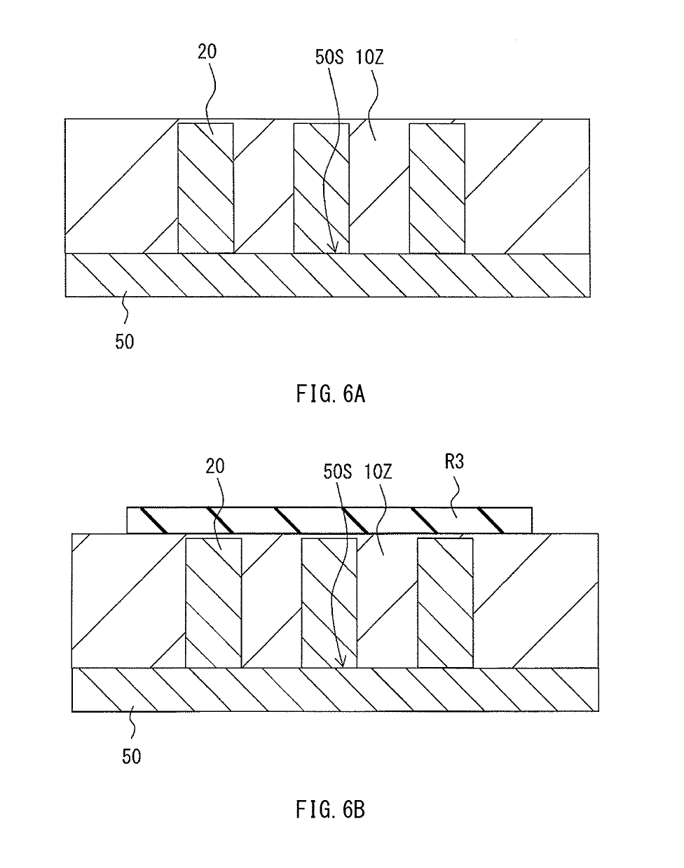

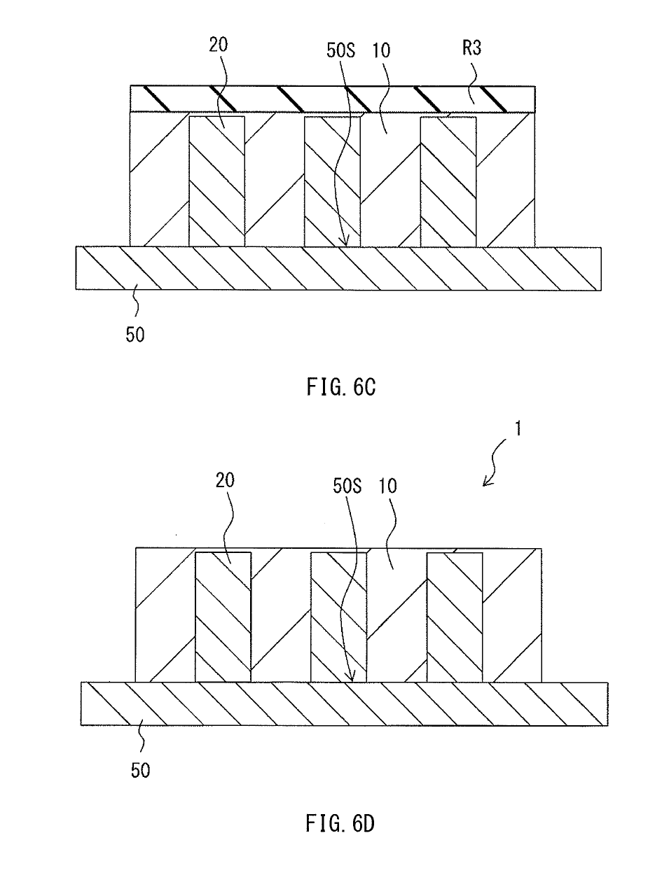

It should also be appreciated that the method of manufacturing the joint structure according to the first embodiment is not to be construed as limiting the disclosure. According to an example modification of the disclosure, the joint structure may be manufactured through processes illustrated in FIGS. 6A to 6D. For example, the plurality of second metal parts 20 may be formed on the ASIC 50 using the resist pattern R1, as illustrated in FIGS. 3A and 3B, and the resist pattern R1 may be removed. Thereafter, with reference to FIG. 6A, regions not provided with the second metal parts 20 may be filled with tin accumulated by sputtering, for example. Thereafter, with reference to FIG. 6B, a resist pattern R3 may be formed to cover a selective region in which the joint structure 1 is to be formed. Using the resist pattern R3 as a mask, the tin accumulated in regions not covered with the resist pattern R3 may be removed by etching, as illustrated in FIG. 6C. Finally, the resist pattern R3 may be removed to produce the joint structure 1 illustrated in FIG. 6D.

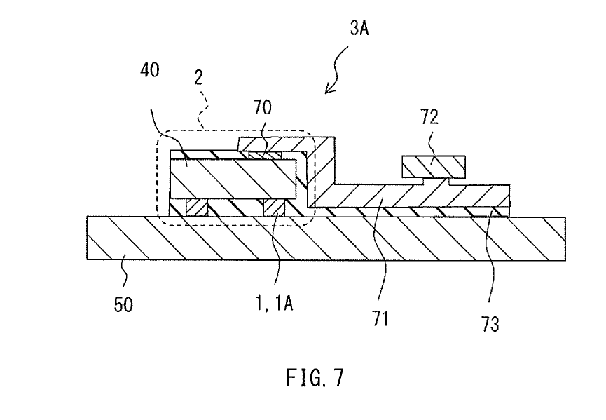

It should also be appreciated that the electronic component unit 3 illustrated in FIG. 2 is not to be construed as limiting the disclosure. In an example modification of the disclosure illustrated in FIG. 7, an electronic component unit 3A may include a first pad 70, a wiring pattern 71, and a second pad 72. The first pad 70 may be disposed on a top surface of the sensor chip 40 provided on the ASIC 50. In other words, the first pad 70 may be disposed on a first surface of the sensor chip 40, and the first surface is opposite to a second surface, facing the ASIC 50, of the sensor chip 40. The wiring pattern 71 may be coupled to the first pad 70. The second pad 72 may be disposed on an edge portion of the wiring pattern 71 and configured to be coupled to an external device. In the electronic component unit 3A, the sensor chip 40 may be mechanically fixed to the surface 50S of the ASIC 50 through the joint structure 1 or 1A. An insulating layer 73 may be provided between the wiring pattern 71 and the ASIC 50. The wiring pattern 71 may be a film formed by plating or sputtering, for example. The wiring pattern 71 may electrically couple the sensor chip 40 and the ASIC 50 to each other, or may electrically couple the sensor chip 40 and an external device to each other. The wiring pattern 71 may correspond to a specific but non-limiting example of a “wiring line” according to one embodiment of the disclosure. The joint structure 1 or 1A having such a structure is highly thermal-resistant and thus resistant to remelting during the reheating, it is possible to form the wiring pattern 71 by plating or sputtering that involves relatively high-heat application, even after the joining of the ASIC 50 and the sensor chip 40 through the joint structure 1 or 1A. Accordingly, the electronic component unit according to the example modification of the disclosure advantageously has a lower profile than the electronic component unit assembled by wire bonding.

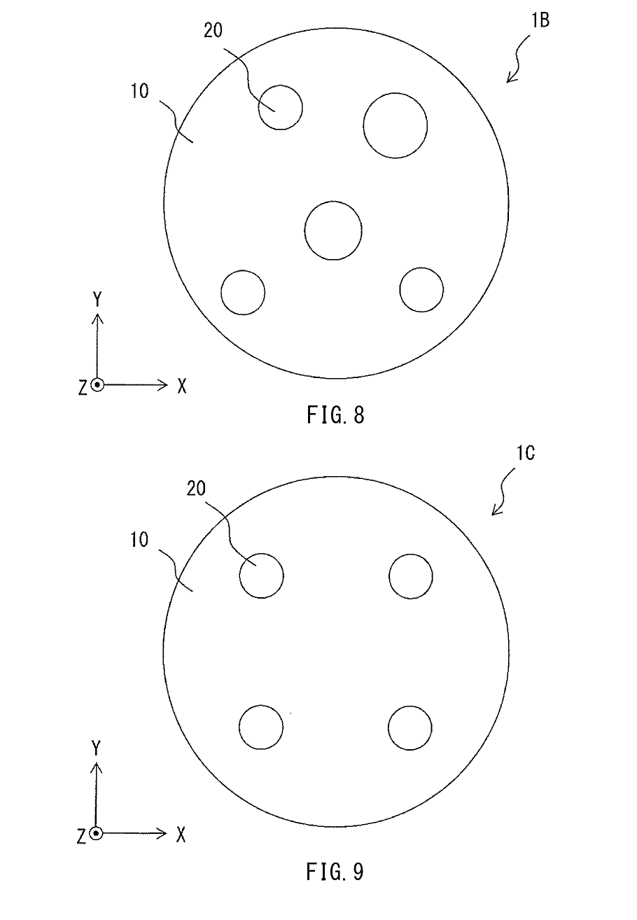

According to any example embodiments of the disclosure, the joint structure may have a part in which the tin content rate repeatedly varies along one or both of the thickness direction and the in-plane direction. It should be appreciated that the example embodiment is not to be construed as limiting the disclosure. The wording “the tin content rate repeatedly varies” as used herein should not be limited to the example embodiment, illustrated in FIG. 1C, for example, in which the tin content rate varies with a strictly regular periodicity. In other words, the disclosure should not be limited to the example embodiment in which the tin-based pillars have the same (identical) diameter and are provided at a regular (equal) interval. In an example modification of the disclosure, illustrated in FIG. 8, for example, a joint structure 1B may include the plurality of pillar-shaped second metal parts 20 of some of which or all of which diameters are different from each other. Additionally, the centers of some or all of the pillar-shaped second metal parts 20 may be positioned at irregular intervals. The same may go for a joint structure that includes the first metal part 1 and the second metal part 2 reversely positioned from that of the joint structure 1B illustrated in FIG. 8. That is, in another example modification of the disclosure, the plurality of pillars are the first metal parts 10, unlike the example modification illustrated in FIG. 8 in which the plurality of pillars are the second metal parts 20.

The joint structure of the disclosure may also encompass a joint structure 1C illustrated in FIG. 9, for example. In the joint structure 1C, the centers of most adjacent pillar-shaped second metal parts 20 may be positioned at a substantially equal interval. Note that the term “substantially equal” as used herein covers slight differences, such as manufacturing errors or measurement errors between the pillar-shaped second metal parts 20, if any. In the example embodiment illustrated in FIG. 9, the plurality of pillars are the second metal parts 20; however, in another example modification of the disclosure, the plurality of pillars may be the first metal parts 10.

In any example embodiments of the disclosure, the sensor included in the sensor chip may be the magneto-resistive element. It should be appreciated that the example embodiment is not to be construed as limiting the disclosure. In an example modification of the disclosure, a Hall element may be used that detect a magnetic field as a physical quantity. In another example modification of the disclosure, a sensor may be used that detects factors other than the magnetic field, such as heat, humid, distortion, or gas, as a physical quantity.

In any example embodiments of the disclosure, the substrates of the electronic components are exemplified as the ASIC 50 and the sensor chip 40. It should be appreciated that the example embodiment is not to be construed as limiting the disclosure. It should also be appreciated that the joint structure may be used to joint any components other than the substrate of electronic components.

The foregoing embodiments and modifications may be applied in any combination.

It should be appreciated that the effects described herein are mere examples. Effects of an example embodiment of the disclosure are not limited to those described herein. The disclosure may further include any effect other than those described herein.

It is possible to achieve at least the following configurations from the above-described example embodiments and modifications of the disclosure.
(1) A joint structure including:
   a first metal part including a nickel-iron alloy or copper; and
   a second metal part provided adjacent to the first metal part and including tin,
      out of the first metal part and the second metal part, the first metal part including a plurality of first metal parts, or
      out of the first metal part and the second metal part, the second metal part including a plurality of second metal parts, or
      the first metal part including a plurality of first metal parts and the second metal part including a plurality of second metal parts.
(2) The joint structure according to (1), in which
   the first metal part further includes a tin-nickel-iron alloy or a tin-copper alloy,
   the second metal part further includes a tin-nickel-iron alloy or a tin-copper alloy, and
   the second metal part has a second tin content rate that is greater than a first tin content rate of the first metal part.
(3) The joint structure according to (1), further including a part in which a tin content rate repeatedly varies along one or both of a thickness direction and an in-plane direction.
(4) The joint structure according to any one of (1) to (3), in which
   the second metal part includes a plurality of second metal parts,
   the plurality of second metal parts include a plurality of pillars, and
   the first metal part is filled in gaps between the plurality of pillars, or in which
   the first metal part includes a plurality of first metal parts,
   the plurality of first metal parts include a plurality of pillars, and
   the second metal part is filled in gaps between the plurality of pillars.
(5) The joint structure according to (4), in which one of the plurality of pillars is surrounded by one or more of the plurality of pillars.
(6) The joint structure according to (4) or (5), in which the plurality of pillars have their respective centers positioned at a substantially equal interval.
(7) The joint structure according to any one of (1) to (3), in which the first metal part and the second metal part are alternately laminated.
(8) The joint structure according to (7), in which
   the second metal part further includes a tin-nickel-iron alloy or a tin-copper alloy, and
   the second metal part includes an uppermost layer of the joint structure.
(9) An electronic component module including:
   an electronic component chip including an electronic component; and
   a joint structure provided on the electronic component chip,
   the joint structure including a first metal part and a second metal part, the first metal part including a nickel-iron alloy or copper, the second metal part being provided adjacent to the first metal part and including tin,
   out of the first metal part and the second metal part, the first metal part including a plurality of first metal parts, or
   out of the first metal part and the second metal part, the second metal part including a plurality of second metal parts, or
   the first metal part including a plurality of first metal parts and the second metal part including a plurality of second metal parts.
(10) An electronic component unit including:
   a first substrate including a first electronic component;
   a second substrate including a second electronic component; and
   a joint structure joining the first substrate and the second substrate,
   the joint structure including a first metal part and a second metal part, the first metal part including a nickel-iron alloy or copper, the second metal part being provided adjacent to the first metal part and including tin,
   out of the first metal part and the second metal part, the first metal part including a plurality of first metal parts, or
   out of the first metal part and the second metal part, the second metal part including a plurality of second metal parts, or
   the first metal part including a plurality of first metal parts and the second metal part including a plurality of second metal parts.
(11) The electronic component unit according to (10), further including:
   a wiring line coupling the first electronic component and the second electronic component, and
   an insulating layer provided between the wiring line and the the first electronic component and the second electronic component.
(12) A method of manufacturing an electronic component unit, the method including:
   forming a joint structure on a first substrate that includes a first electronic component, the joint structure including a first metal part that includes a nickel-iron alloy or copper and a second metal part that is provided adjacent to the first metal part and includes tin,
      out of the first metal part and the second metal part, the first metal part including a plurality of first metal parts, or
      out of the first metal part and the second metal part, the second metal part including a plurality of second metal parts, or
      the first metal part including a plurality of first metal parts and the second metal part including a plurality of second metal parts;
   providing a second substrate on a first surface of the joint structure, the second substrate including a second electronic component, the first surface of the joint structure being opposite to a second surface of the joint structure, the second surface of the joint structure facing the first substrate; and
   forming an alloy of the nickel-iron alloy or the copper included in the first metal part and the tin included in the second metal part by heating the first metal part and the second metal part.

In the joint structure, the electronic component module, and the electronic component unit according to any example embodiment of the disclosure, the one or more first metal parts include a nickel-iron alloy or copper, and the one or more second metal parts include tin. The first metal part(s) and the second metal part(s) may be provided adjacent to each other at two or more portions. Accordingly, the two or more alloy regions each including an alloy of the constituent element in the first metal part and the constituent element in the second metal part may be formed after the heating process. This raises the melting point of the joint structure, improves structural uniformity across the entire joint structure, and reduces variations in quality of the joint structure.

In the method of manufacturing the electronic component unit according to any example embodiment of the disclosure, the one or more first metal parts include a nickel-iron alloy or copper, and the one or more second metal parts include tin. The first metal part(s) and the second metal part(s) may be provided adjacent to each other at two or more portions. Accordingly, the two or more alloy regions each including an alloy of the constituent element in the first metal part and the constituent element in the second metal part may be formed after the heating process. This raises the melting point of the joint structure, improves structural uniformity across the entire joint structure, and reduces variations in quality of the joint structure.

According to any embodiment of the disclosure, it is possible to ensure the superior quality of the joint structure, the electronic component module, and the electronic component unit. Further, it is possible to produce the electric component unit having the superior quality by the method of manufacturing the electronic component unit according to any example embodiment of the disclosure.

Although the disclosure has been described in terms of example embodiments, it is not limited thereto. It should be appreciated that variations may be made in the described embodiments by persons skilled in the art without departing from the scope of the disclosure as defined by the following claims. The limitations in the claims are to be interpreted broadly based on the language employed in the claims and not limited to examples described in this specification or during the prosecution of the application, and the examples are to be construed as non-exclusive. For example, in this disclosure, the use of the terms first, second, etc. do not denote any order or importance, but rather the terms first, second, etc. are used to distinguish one element from another. Moreover, no element or component in this disclosure is intended to be dedicated to the public regardless of whether the element or component is explicitly recited in the following claims.

What is claimed is:

1. A joint structure comprising:
a first metal part including a nickel-iron alloy or copper; and
a second metal part provided adjacent to the first metal part and including tin,
out of the first metal part and the second metal part, the first metal part comprising a plurality of first metal parts, or
out of the first metal part and the second metal part, the second metal part comprising a plurality of second metal parts, or
the first metal part comprising a plurality of first metal parts and the second metal part comprising a plurality of second metal parts.

2. The joint structure according to claim 1, wherein
the first metal part further includes a tin-nickel-iron alloy or a tin-copper alloy,
the second metal part further includes a tin-nickel-iron alloy or a tin-copper alloy, and
the second metal part has a second tin content rate that is greater than a first tin content rate of the first metal part.

3. The joint structure according to claim 1, further comprising a part in which a tin content rate repeatedly varies along one or both of a thickness direction and an in-plane direction.

4. The joint structure according to claim 1, wherein
the second metal part comprises a plurality of second metal parts,
the plurality of second metal parts comprise a plurality of pillars, and
the first metal part is filled in gaps between the plurality of pillars, or wherein
the first metal part comprises a plurality of first metal parts,
the plurality of first metal parts comprise a plurality of pillars, and
the second metal part is filled in gaps between the plurality of pillars.

5. The joint structure according to claim 4, wherein one of the plurality of pillars is surrounded by one or more of the plurality of pillars.

6. The joint structure according to claim 4, wherein the plurality of pillars have their respective centers positioned at a substantially equal interval.

7. The joint structure according to claim 1, wherein
the first metal part and the second metal part are alternately laminated.

8. The joint structure according to claim 7, wherein
the second metal part further includes a tin-nickel-iron alloy or a tin-copper alloy, and
the second metal part comprises an uppermost layer of the joint structure.

9. An electronic component module comprising:
an electronic component chip including an electronic component; and
a joint structure provided on the electronic component chip,
the joint structure including a first metal part and a second metal part, the first metal part including a nickel-iron alloy or copper, the second metal part being provided adjacent to the first metal part and including tin,
out of the first metal part and the second metal part, the first metal part comprising a plurality of first metal parts, or
out of the first metal part and the second metal part, the second metal part comprising a plurality of second metal parts, or
the first metal part comprising a plurality of first metal parts and the second metal part comprising a plurality of second metal parts.

10. An electronic component unit comprising:
a first substrate including a first electronic component;
a second substrate including a second electronic component; and
a joint structure joining the first substrate and the second substrate,
the joint structure including a first metal part and a second metal part, the first metal part including a nickel-iron alloy or copper, the second metal part being provided adjacent to the first metal part and including tin,
out of the first metal part and the second metal part, the first metal part comprising a plurality of first metal parts, or
out of the first metal part and the second metal part, the second metal part comprising a plurality of second metal parts, or
the first metal part comprising a plurality of first metal parts and the second metal part comprising a plurality of second metal parts.

11. The electronic component unit according to claim 10, further comprising:
a wiring line coupling the first electronic component and the second electronic component, and
an insulating layer provided between the wiring line and the the first electronic component and the second electronic component.

12. A method of manufacturing an electronic component unit, the method comprising:
forming a joint structure on a first substrate that includes a first electronic component, the joint structure including a first metal part that includes a nickel-iron alloy or copper and a second metal part that is provided adjacent to the first metal part and includes tin,
out of the first metal part and the second metal part, the first metal part comprising a plurality of first metal parts, or
out of the first metal part and the second metal part, the second metal part comprising a plurality of second metal parts, or
the first metal part comprising a plurality of first metal parts and the second metal part comprising a plurality of second metal parts;
providing a second substrate on a first surface of the joint structure, the second substrate including a second electronic component, the first surface of the joint structure being opposite to a second surface of the joint structure, the second surface of the joint structure facing the first substrate; and
forming an alloy of the nickel-iron alloy or the copper included in the first metal part and the tin included in the second metal part by heating the first metal part and the second metal part.
